(19) United States
(12) Patent Application Publication
(10) Pub. No.: US 2026/0246462 A1
(43) Pub. Date: Aug. 20, 2026

(54) HIGH-SIDE DRIVERS PROVIDING ADAPTIVE POWER DELIVERY

(71) Applicant: Allegro MicroSystems, LLC, Manchester, NH (US)

(72) Inventor: Guillaume Aulagnier, Cannes (FR)

(73) Assignee: Allegro MicroSystems, LLC, Manchester, NH (US)

(21) Appl. No.: 19/058,560

(22) Filed: Feb. 20, 2025

(51) Int. Cl. H03K 17/20

(52) U.S. Cl. CPC H03K 17/20; H03K 2217/0027; H03K 2217/0063; H03K 2217/0081

(57) ABSTRACT

Systems, structures, packages, circuits, and methods provide gate drivers providing adaptive power refresh techniques for high-side drivers used to control operation of power (switching) devices such a MOSFETs or other transistors. One or more time-to-voltage circuits are used to measure ON times of input control voltage signals of a gate driver. Each time-to-voltage circuit includes an input, a first switch connected to the input, a current source, a capacitor, and a reset switch configured in parallel with capacitor. Measurement of ON times of successive pulses are used to control a voltage controlled oscillator, which is used to generate refresh power pulses at timing positions distinct from the input control voltage signals to avoid pulse clash while providing sufficient power to high-side circuitry.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to separate voltage potentials. Such galvanic isolation can be used to separate circuits in order to protect users from coming into direct contact with hazardous voltages.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits.

For magnetically coupled isolated gate drivers, a challenge arises when transferring power and signal to the high side of the circuit (where “high-side” refers to the device being placed between the positive power line and the load in the circuit), particularly at low frequencies. At lower frequencies, the incoming signal pulses may not occur frequently enough to sustain a minimum power level on the high side of the driver circuit. This minimum power level can be crucial for maintaining appropriate logic and bias conditions. To address this issue, one approach involves generating refresh pulses sent to the high side to ensure a consistent power level. However, a drawback arises when these refresh pulses coincide with points where the input signal is changing. This coincidence can lead to signal distortion as received on the high side.

FIGS. 1A-1C show a circuit diagram and two timing diagrams, respectively for a prior art galvanically-isolated gate driver 100. Gate driver 100 includes an input 101 configured to receive one or more control pulses 102, and pulse generator 103. Pulse generator 103 is configured to receive the control pulse(s) 102 and generate corresponding positive signal pulse(s) S_{P} 104 and negative signal pulse(s) S_{N} 105, which are provided to transformer 106 at the primary side (coil) 107, e.g., via first and second CMOS inverters 109, 110, respectively. The secondary side (coil) 108 of transformer 106 provides the positive signal pulse(s) S_{P} 104 and negative signal pulse(s) S_{N} 105 to rectifier 111 and signal detector (signal detect block) 112 via connections as shown. Rectifier 111 is configured to provide power to high-side circuitry at connections 111a-111b, e.g., for driven device 120. A signal detector 112 is configured to provide an output voltage signal 113 at connections 112a-112b, which may be used for control of, e.g., for driven device 120. The scheme shown in FIG. 1A sends power and a signal to the high side circuitry, where “high side” refers to the circuitry being placed between the positive power line and the load in the circuit.

As shown in FIG. 1B, the pulses seen at S_{P} (positive signal pulse) and S_{N} (negative signal pulse) are sent across the magnetic isolation boundary provided by transformer 106 and are used to set and reset a latch in the signal detect block 112 and thus generate the input signal (for controlling the device to be switched).

The scheme works well when the pulses S_{P} and S_{N} generated by the input signal (V_{IN}) occur frequently. This allows adequate power to be harvested by the high side rectifier 111 to power the bias and logic circuits on the high side.

When the frequency of the incoming signal (e.g., V_{IN} 102) is too low, however, the signal pulses don't occur frequently enough to supply sufficient power to the high-side circuitry. For this reason, additional pulses, called refresh pulses, are typically generated which further pulse energy across the transformer 106 and maintain the power level in the system. The pulse generator (generation) circuit in FIG. 1A accepts the refresh pulse and passes it through to generate the pulse that impacts the S_{P} node. The scheme is sensible in that the refresh pulse Rp is sent as a positive pulse and this only reaffirms the latch in the high side signal detect block 112.

FIG. 1C shows the scenario of FIG. 1B with the refresh pulses shown with a greater degree of delay. In the case shown in FIG. 1C, the refresh pulse generates a pulse at S_{P} which is coincident in time with Sn. This can be referred to as a pulse conflict or pulse clash. The consequence of the pulse clash is that there is no net voltage across the primary of the transformer for the duration of this clash—as S_{P} and S_{N} both go to positive supply voltage (V_{DD}) during a clash. This results in no power transfer and the negative edge of Vin is also missing. Thus, FIG. 1C illustrates an inherent problem of the prior art driver 100 of FIG. 1A: pulse-collision or pulse-clash at low operational frequencies.

### SUMMARY

Aspects of the present disclosure are directed to gate drivers, related packages, and related fabrication methods providing adaptive power refresh techniques for high-side drivers used to control operation of power (switching) devices.

In one aspect, an adaptive power delivery circuit for an isolated gate driver comprises: an isolation transformer including a primary coil and a secondary coil; control circuitry, including a control signal pulse generator having an input and an adaptive timing circuit, connected to the primary coil, wherein the control signal pulse generator is configured to receive control signals (V_{IN}) at the input and generate corresponding positive and negative control signal pulses; and wherein the adaptive timing circuit is configured to produce refresh pulses to provide necessary power to the gate driver, wherein the refresh pulses have adaptively positioned timing to avoid coinciding with the control signal pulses; and a rectifier connected to the secondary coil, wherein the rectifier is configured to harvest power from the pulses received by the secondary coil and provide power to the gate driver; and a signal detector connected to the secondary coil and configured to detect the control signal pulses and based on the detected control signal pulses provide isolated control signals to the gate driver.

A circuit can further include or more of the following features: the adaptive timing circuit includes first and second time-to-voltage circuits connected to a multiplexor, wherein each time-to-voltage circuit is configured to receive, at an input, the control signals (V_{IN}) and produce as an output signal an output voltage (V_{T}) proportional to an ON time (T_{ON}) wherein a control signal (V_{IN}) exceeds a predetermined threshold, each time-to-voltage circuit includes a switch configured between a current source and a capacitor (C₁), wherein the switch is configured to be activated by the control signals (V_{IN}), the multiplexor is configured to produce an output signal (V_{T}) that includes the output signal (V_{TON1}) from the first time-to-voltage circuit at a first time cycle (N) and the output signal (V_{TON2}) from the second time-to-voltage circuit at a subsequent time cycle (N+1), the multiplexor is configured to produce the output signal (V_{T}) as the output signal from the first time-to-voltage circuit alternating, on a cycle-by-cycle basis, with the output signal from the second time-to-voltage circuit, the adaptive timing circuit further comprises a voltage-controlled oscillator (VCO) circuit configured to receive the output signal (V_{T}) from the multiplexor and produce the refresh pulses with a desired time period between successive refresh pulses, the desired time period is a selected fraction of the time period corresponding to the multiplexor output signal (V_{T}) for a given time cycle, the VCO circuit comprises a switch configured between a current source and a charging capacitor (C₂), and wherein the VCO circuit includes a comparator configured to generate a refresh pulse when a voltage across the charging capacitor (C₂) exceeds a threshold voltage, the charging capacitor (C₂) is substantially equal to the capacitor (C₁) of the time-to-voltage circuits, the VCO circuit is configured to start an oscillator cycle at a rising edge of a control signal pulse, the current source of the VCO circuit includes a current mirror, and wherein the VCO circuit is configured to provide a current that is a desired scalar multiple (X) of the current source of the time-to-voltage circuits, the VCO circuit has an oscillator cycle period that is a corresponding reciprocal scaled version (1/X) of the cycle period of multiplexor output signal (V_{T}) for a given time cycle (N), threshold voltage is set to the multiplexor output signal (V_{T}), the adaptive timing circuit is configured to produce a plurality of refresh pulses for a given time cycle (N), a refresh rate (NR) of the plurality of refresh pulses is given by

$${N}_{R} = \frac{{T}_{ON} \times 2}{( 1 + 2 \times {N}_{R} )} ,$$

wherein T_{ON} is the ON time corresponding to the multiplexor output signal (V_{T}) for a current time cycle, for T_{ON} exceeding a predetermined threshold time, the adaptive timing circuit is configured to set the oscillator threshold voltage to a first desired voltage (V_{TRMIN1}) corresponding to a first desired refresh pulse rate (T_{RMIN1}), in response to a pulse clash, the adaptive timing circuit is configured to switch the oscillator threshold voltage from the first desired voltage (V_{TRMIN1}) corresponding to the first desired refresh pulse rate (T_{RMIN1}) to a second desired voltage (V_{TRMIN2}) corresponding to a second desired refresh pulse rate (T_{RMIN2}), the second desired pulse rate (T_{RMIN2}) is withing a range of about ±5% of the first desired pulse rate (T_{RMIN1}), threshold is set to the multiplexor output signal (V_{T}), the capacitor is configured in parallel with a reset switch configured to receive the refresh pulse from the oscillator as a reset pulse, the signal detector includes a latch, wherein positive and negative pulses received from the secondary coil operate to set and reset the latch to form the control signal pulses, an inverter provided at the input to the control signal pulse generator, and/or a gate driver connected to the secondary coil, wherein the gate driver is configured to control operation of a semiconductor power switch.

In another aspect, a method of making an adaptive power delivery circuit for providing power to a gate driver comprises: providing an isolation transformer including a primary coil and a secondary coil; providing control circuitry, including a control signal pulse generator having an input and an adaptive timing circuit, connected to the primary coil, wherein the control signal pulse generator is configured to receive control signals (V_{IN}) at the input and generate corresponding positive and negative control signal pulses; and wherein the adaptive timing circuit is configured to produce refresh pulses to provide necessary power to the gate driver, wherein the refresh pulses have adaptively positioned timing to avoid coinciding with the control signal pulses; and providing a rectifier connected to the secondary coil, wherein the rectifier is configured to harvest power from the pulses received by the secondary coil and provide power to the gate driver; and providing a signal detector connected to the secondary coil and configured to detect the control signal pulses and based on the detected control signal pulses provide isolated control signals to the gate driver.

A method can further include one or more of the following features: the adaptive timing circuit includes first and second time-to-voltage circuits connected to a multiplexor, wherein each time-to-voltage circuit is configured to receive, at an input, the control signals (V_{IN}) and produce an output voltage proportional to an ON time (T_{ON}) wherein a control signal (V_{IN}) exceeds a predetermined threshold, each time-to-voltage circuit includes a switch configured between a current source and a capacitor (C₁), wherein the switch is configured to be activated by the control signals (V_{IN}), the multiplexor is configured to produce an output signal (V_{T}) that includes the output signal (V_{TON1}) from the first time-to-voltage circuit at a first time cycle (N) and the output signal (V_{TON2}) from the second time-to-voltage circuit at a subsequent time cycle (N+1), the multiplexor is configured to produce the output signal (V_{T}) as the output signal from the first time-to-voltage circuit alternating, on a cycle-by-cycle basis, with the output signal from the second time-to-voltage circuit, the adaptive timing circuit further comprises a voltage-controlled oscillator (VCO) circuit configured to receive the output signal (V_{T}) from the multiplexor and produce the refresh pulses with a desired time period between successive refresh pulses, the desired time period is a selected fraction of the time period corresponding to the multiplexor output signal (V_{T}) for a given time cycle, the VCO circuit comprises a switch configured between a current source and a charging capacitor (C₂), and wherein the VCO circuit includes a comparator configured to generate the oscillator output pulse when a voltage across the charging capacitor exceeds a threshold voltage, the charging capacitor (C₂) is substantially equal to the capacitor (C₁) of the time-to-voltage circuits, the VCO circuit is configured to start an oscillator cycle at a rising edge of a control signal pulse, the current source of the VCO circuit includes a current mirror, and wherein the VCO circuit is configured to provide a current that is a desired scalar multiple (X) of the current source of the time-to-voltage circuits, the VCO circuit has an oscillator cycle period that is a corresponding reciprocal scaled version (1/X) of the cycle period of multiplexor output signal (V_{T}) for a given time cycle (N), threshold voltage is set to the multiplexor output signal (V_{T}), the adaptive timing circuit is configured to produce a plurality of refresh pulses for a given time cycle (N), a refresh rate (NR) of the plurality of refresh pulses is given by

$${N}_{R} = \frac{{T}_{ON} \times 2}{( 1 + 2 \times {N}_{R} )} ,$$

wherein T_{ON} is the ON time corresponding to the multiplexor output signal (V_{T}) for a current time cycle, for T_{ON} exceeding a predetermined threshold time, the adaptive timing circuit is configured to set the oscillator threshold voltage to a first desired voltage (V_{TRMIN1}) corresponding to a first desired refresh pulse rate (T_{RMIN1}), in response to a pulse clash, the adaptive timing circuit is configured to switch the oscillator threshold voltage from the first desired voltage (V_{TRMIN1}) corresponding to the first desired refresh pulse rate (T_{RMIN1}) to a second desired voltage (V_{TRMIN2}) corresponding to a second desired refresh pulse rate (T_{RMIN2}), the second desired pulse rate (T_{RMIN2}) is withing a range of about ±5% of the first desired pulse rate (T_{RMIN1}), threshold is set to the multiplexor output signal (V_{T}), the capacitor is configured in parallel with a reset switch configured to receive the refresh pulse from the oscillator as a reset pulse, the signal detector includes a latch, wherein positive and negative pulses received from the secondary coil operate to set and reset the latch to form the control signal pulses, providing an inverter provided at the input to the control signal pulse generator, and/or providing a gate driver connected to the secondary coil, wherein the gate driver is configured to control operation of a semiconductor power switch.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIGS. 1A-1C show a circuit diagram and two timing diagrams, respectively for a prior art galvanically-isolated gate driver;

FIG. 2 shows a circuit diagram of an example high-side gate driver circuit providing adaptive power refresh pulse timing in accordance with the present disclosure;

FIGS. 3A-3B show an example time-to-voltage circuit and related timing diagram, respectively in accordance with the present disclosure;

FIG. 4 shows an example dual time-to-voltage circuit in accordance with the present disclosure;

FIG. 5 shows an example timing diagram for the circuit of FIG. 4;

FIGS. 6A-6B show an oscillator circuit configured to produce a frequency which depends on a time-on measurement voltage and an example corresponding timing diagram, in accordance with the present disclosure;

FIG. 7 is an example timing diagram representing an equation of pulse positions verses number of refresh pulses in accordance with the present disclosure;

FIG. 8 is a diagram showing an example method of fabricating a high-side driving providing adaptive power pulse timing, in accordance with the present disclosure; and

FIG. 9 shows an example computing system in accordance with the present disclosure.

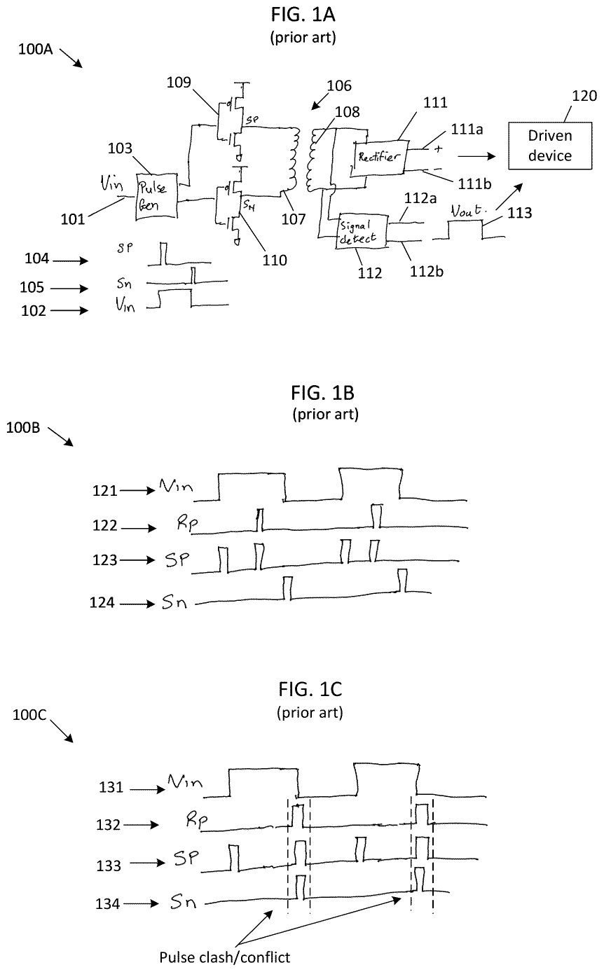

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects, examples, and embodiments of the present disclosure are directed to and include systems, circuitry, and methods (schemes) that adaptively position the required refresh pulses. In doing so, such systems, circuitry and methods can avoid the problems of refresh pulses coinciding with input signal changes (pulse clash), thereby preserving the integrity of the signal received on the high side of the circuit. This adaptive positioning can ensure that the refresh pulses effectively maintain the necessary power levels without compromising the quality of the transmitted signal.

Such assemblies, structures, and packages can be used for systems, structures, and circuits providing galvanic isolation (a.k.a., voltage isolation), e.g., for high-voltage applications. In some embodiments, a transformer with a core may have, e.g., a step up, a step down, or a power transformer configuration. In some embodiments, a transformer may have multiple input and/or output coils/coil structures.

The transformer assemblies and packages (modules) may include various types of circuits (e.g., ICs); in some examples, transformer packages with ICs may include a galvanically isolated gate driver or other high voltage circuit, etc. One or more (e.g., first and second) semiconductor die having one or more integrated circuits (a.k.a., “IC die”) can be included in the packages and assemblies. Such integrated circuits can include, e.g., but are not limited to, high-voltage circuits such as galvanically-isolated gate drivers configured to drive an external gate on a solid-state (semiconductor) switch, e.g., a field effect transistor (FET), a metal oxide semiconductor (MOS) FET (MOSFET), a metal semiconductor FET (MESFET), a gallium nitride FET (GaN FET), a high electron mobility transistor (HEMT), a silicon carbide FET (SiC FET), an insulated gate bipolar transistor (IGBT), or another load.

Aspects and embodiments of the present disclosure, address the above-described pulse-clash (pulse-conflict) problem, and provide a solution that involves positioning refresh power pulses to avoid clashing with incoming control signal pulses, e.g., the incoming negative edge of V_{IN}. To achieve this, a prediction of the position of the negative edge of Vin is provided. This prediction is made by understanding where the negative edge arrived in the previous cycle. This is then used as an estimate of where it might arrive in the next cycle. This is done with an understanding that in normal operation the “On” time of an input signal does not change much from cycle to cycle. For refresh-pulse timing, a measure of the T_{ON} of a previous cycle is used, in conjunction with the positive edge of V_{IN} of a present cycle, to predict the position of the negative edge of the V_{IN} pulse.

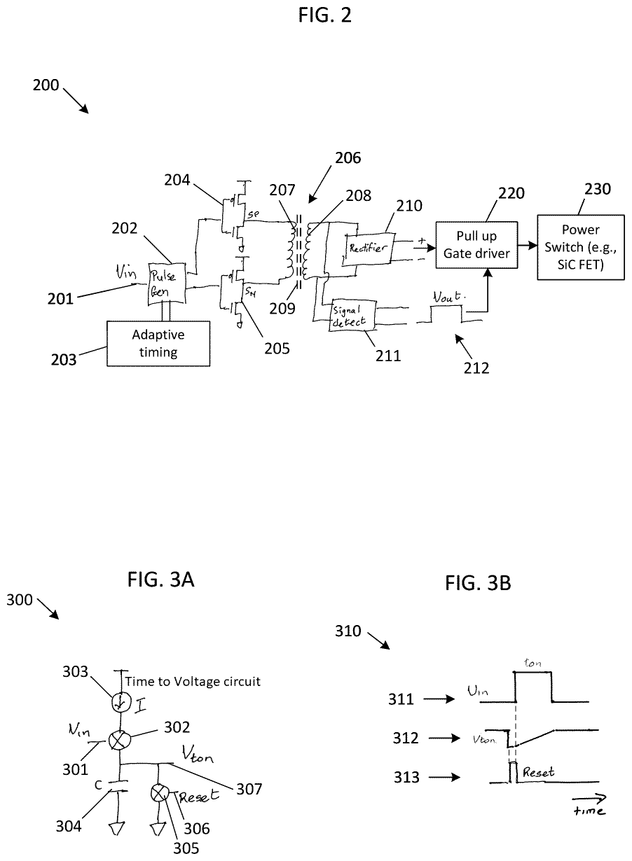

FIG. 2 shows a circuit diagram of an example high-side gate driver circuit 200 providing adaptive power refresh pulse timing in accordance with the present disclosure. Gate driver circuit (gate driver) 200 includes an input 201 configured to receive one or more control pulses 202, and pulse generator 203. Pulse generator 203 is configured to receive the control pulse(s) 202 and generate corresponding positive signal pulse(s) S_{P} 204 and negative signal pulse(s) S_{N} 205, which are provided to transformer 206 at the primary side (coil) 207 via suitable connections, e.g., including first and second transistor pairs such as CMOS inverters 209, 210, respectively. The secondary side (coil) 208 of transformer 206 provides the positive signal pulse(s) S_{P} 204 and negative signal pulse(s) S_{N} 105 to rectifier 211 and signal detector (signal detect block) 212 via connections as shown. Rectifier 211 is configured to provide power to high-side circuitry at connections 211a-211b, e.g., for driven device (e.g., MOSFET) 220. A signal detector 212 is configured to provide an output voltage signal 213 at connections 212a-212b, which may be used for control of, e.g., for driven device 220. The scheme shown in FIG. 2 sends power and a signal to the high side circuitry, where “high side” refers to the circuitry being placed between the positive power line and the load in the circuit.

FIGS. 3A-3B show an example time-to-voltage circuit 300 and related timing diagram 310, respectively, in accordance with the present disclosure.

Time-to-voltage circuit 300 includes an input 301 configured to receive V_{IN}, a first (main) switch 302 connected to input 301 and configured in a closed state to receive current from current source (generator) 303, and capacitor (C) 304. Circuit 300 includes an output 307 providing a V_{TON} signal corresponding (e.g., proportional) to a time that V_{IN} is ON (see FIG. 3B), e.g., above a threshold voltage. Circuit 300 also includes a reset switch 305 having an input 306, which is configured in parallel with capacitor 304 and includes input 306, e.g., configured to receive a reset signal (pulse).

Timing diagram 310 of FIG. 3B shows a representative signal flow for operation of circuit 300A, with V_{IN}, V_{TON}, and RESET signal lines 311, 312, and 313, respectively, indicated.

In operation, circuit 300 provides a measurement of T_{ON}, by producing a voltage which is proportional to T_{ON}. Timing diagram 310 shows how switch 302 (attached to input 301 receiving V_{IN}) is turned on (i.e., closes) when V_{IN} goes high. Switch 302 remains closed for the duration of the positive excursion of V_{IN} received on input 301. Capacitor 304 charges for as long as switch 302 is on. When V_{IN} drops low (turns off), switch 302 is opened, and capacitor 304 retains (remembers) the voltage at the time switch 302 is opened and provides that voltage at output 307. Before the next cycle begins, reset switch 305 (connecting capacitor 304 to ground) is closed by a reset pulse received at switch input 306. Reset switch 305, when closed, is configured to connect capacitor 304 to ground. Thus, capacitor 304 is discharged to ground by the reset pulse received on input 306. The measured voltage V_{TON} corresponding to the time V_{IN} (and thus, switch 302) is on, increases with the charge applied to capacitor 304, as shown by V_{TON} line 312 in FIG. 3B.

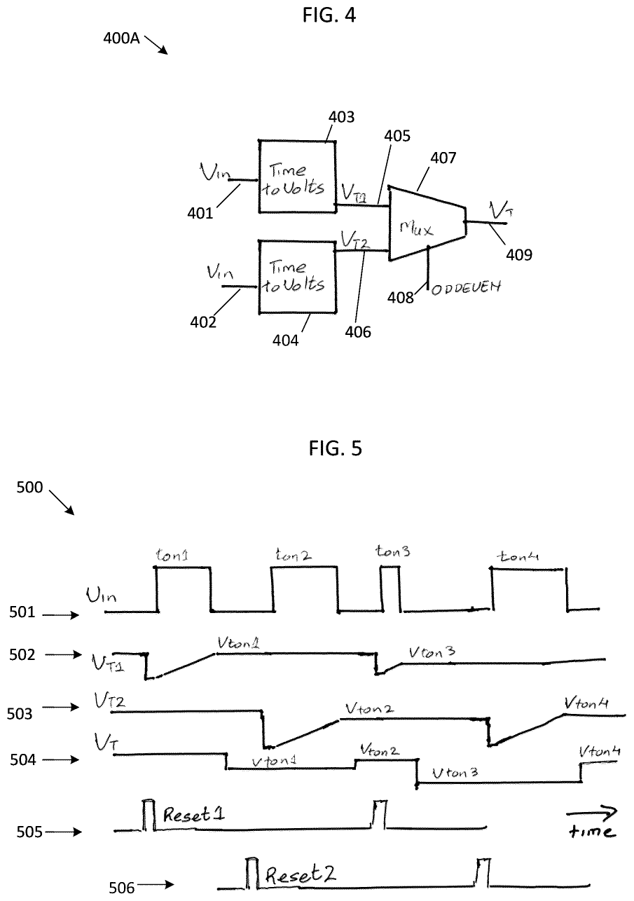

To use the T_{ON} measurement (V_{TON}) of the previous cycle (e.g., N−1) to make predictions for the current cycle (e.g., N), a second time to volts circuit can be employed to measure the T_{ON} of the current cycle while the previous T_{ON} measurement is being used. To achieve this, two time-to-voltage circuits can be used in an alternating (e.g., “ping pong”) fashion, for example as shown in FIG. 4.

FIG. 4 shows an example dual time-to-voltage circuit 400 in accordance with the present disclosure. Circuit 400 includes two time-to-voltage blocks and is configured to measure ON time for successive input pulses (V_{IN}) over successive cycles, e.g., cycle N and cycle N+1, in an alternating (“ping pong”) fashion.

Circuit 400 includes first and second inputs 401, 402, which are configured to receive input pulses (V_{IN}) and connected to first and second time-to-voltage (blocks) circuits 403, 404, respectively. In some embodiments, each of (blocks) circuits 403, 404 is similar to time-to-voltage circuit 300 of FIG. 3A. Circuits 403, 404 provide respective output voltages V_{T1} and V_{T2}, as measures of the ON time of the input pulses (e.g., of V_{IN} at different timing cycles), by connections 405, 406 to multiplexor 407. Multiplexor 407 is shown with input 408, which can serve to switch (toggle) between V_{T1} and V_{T2} being output) as V_{T} on output 409.

In operation of circuit 400, the first time-to-voltage circuit 403 measures the ON time (T_{ON}) of V_{IN} for a first cycle (e.g., N) and outputs the voltage corresponding to this measurement for the following cycle (e.g., N+1). The second circuit 404 measurements the ON time (T_{ON}) for the subsequent cycle (e.g., N+1) and outputs the result in time for use in next successive cycle (e.g., N+2). See FIG. 5 for an example of timing details.

FIG. 5 shows an example timing diagram 500 for the dual time-to-voltage circuit 400 of FIG. 4. In FIG. 5, the output and internal waveforms of circuit 400 are shown for an example situation over four timing cycles.

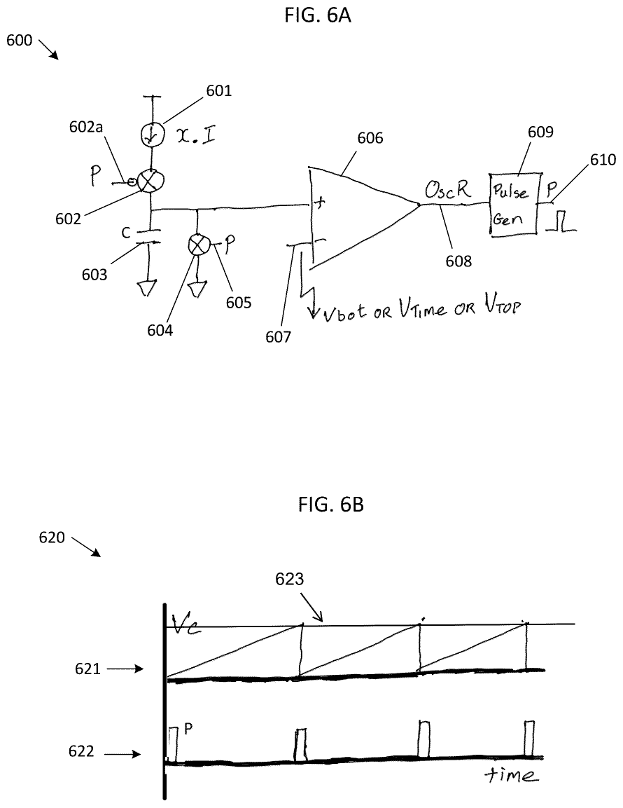

As shown in FIG. 5, in operation of circuit 400, V_{IN} is fed to both first and second time-to-voltage blocks 403, 404. The first time-to-voltage block 403 receives V_{IN} on input 401, with V_{IN} indicated at line 501, measures the time the pulse during a first timing cycle (e.g., N) is above a threshold, i.e., time ON (T_{ON1}), and produces the corresponding measurement voltage, V_{TON1}, as shown for V_{T1} line 502. The second time-to-voltage block 404 follows by measuring the time the pulse on V_{IN} for a subsequent timing cycle (e.g., N+1) is above a threshold (ton2) and produces the measurement V_{TON2}, as shown for V_{T2} line 503. The multiplexor (MUX) 407 of circuit 400, connects (concatenates) V_{T1} and V_{T2} in turn to the output 409 as output voltage V_{T} which can be used to drive an oscillator (e.g., as shown and described for FIGS. 6A-6B) used to produce power refresh pulses, e.g., for circuit 200 of FIG. 2 or a similar circuit in accordance with the present disclosure; signals generated by such an oscillator may also be used as reset pulses for related circuitry, shown on lines 505, 506.

FIG. 6A shows an oscillator circuit 600 configured to produce a frequency which depends on a time-on voltage (V_{T}) in accordance with the present disclosure. Oscillator circuit 600 may be referred to as a voltage-controlled oscillator (VCO) circuit. Circuit 600 includes current source 601, switch 602, and capacitor 603. Switch 602 is configured to receive a pulse (P) at input 602a and to remain closed while pulse P is high. Another switch, switch 604 is configured in parallel with capacitor 603 and is configured to discharge capacitor 603 to ground in response to receiving a signal (e.g., a reset pulse) at input 605.

Oscillator circuit 600 further includes comparator 606 and pulse generator 609. Comparator 606 includes an input 607 configured to supply a trip point value for comparator 607. Comparator 606 provides an output, shown at 608, to pulse generator 609, which generates a corresponding pulse (shown as “P”) at output 610.

FIG. 6B shows an example timing diagram 620 for oscillator circuit 600 of FIG. 6A. Waveforms 621 and 622 in FIG. 6B correspond to operation of oscillator circuit 600 for an example scenario and line 623 may correspond to trip point 607 in FIG. 6A. As indicated at the start of each cycle a pulse P is produced which discharges capacitor 603 to ground. When this pulse P is finished, the current source (X·I) 601 starts to charge capacitor 603 again. Capacitor 603 charges to the trip point (indicated at 607) of comparator 606; in some embodiments, the trip point 607 is normally V_{T} (or V_{TIME}), i.e., the voltage (measurement) corresponding to time-ON (T_{ON}). Other values can be used for the trip point 607 in other embodiments, e.g., it can alternatively be V_{BOT}, V_{TOP}, etc.

When the comparator 606 then reaches its trip point (i.e., trips) it sends a corresponding signal to pulse generator 609, which then produces another pulse (P) at output 610 and thus repeats the cycle.

If the current flowing in the current source 601 is I then then the period of the oscillator would be very close to T_{ON} (provided the pulse P is short with respect to T_{ON}). This also presume that the capacitor in the time-to-voltage converter circuit (e.g., capacitor 304 shown in FIG. 3A) is also of value C.

Because the current scalar (shown as “x”) is easily implementable, e.g., with a current mirror (not shown), the oscillation period can be scaled to be any fraction or multiple of T_{ON}. For example, the oscillation period can be made to be 0.5 (½), 0.333 (⅓), or 0.25 (¼) times the T_{ON} of V_{IN} by suitable selection of scalar X. If the oscillator cycle is started at the rising edge of the V_{IN} voltage, the pulses generated by the oscillator in FIG. 6B can be used as refresh power pulses—e.g., for circuit 200 or similar circuits in accordance with the present disclosure—and can be positioned so that they do not clash with the negative edge of the V signal.

Accordingly, circuit 600 can be used to facilitate appropriate pulse positioning and/or to allow selection of how many pulses to make during T_{ON}. The selected number of pulses might range from one pulse to eight (8) pulses, for example, in some embodiments; other numbers of pulses may be used in other embodiments. This pulse positioning and/or selection of number of pulses can serve to maintain power at the high side of the gate driver even when the on-time of the V_{IN} signal is very long.

The way in which the number of pulses is decided may be, e.g., via a lookup table which maps the measured T_{ON} to the number of pulses. If the current sources and capacitors used in the T_{ON} measurement circuit (e.g., circuit 300 of FIG. 3A) are the same as those used in the oscillator circuit (circuit 600 of FIG. 6A), it is straight forward to scale the oscillator to provide a known number of pulses during the T_{ON} period and avoid clashes with the incoming edge of the V_{IN}.

To avoid clashing and to maximize possible T_{ON} (T_{OFF}) variations from one cycle to the next (cycle N to cycle N+1), the refresh pulses are preferably positioned so that the signal pulse of opposite polarity is mid-way (exactly or approximately) between the last refresh pulse and the next “potential” refresh pulse. Table 1 (below) shows an example of the Refresh rate required for the chosen (selected) pulse number, in accordance with example embodiments of the present disclosure.

In some embodiments, if more than one refresh pulse is required (e.g., for sufficient power on the high side of a gate driver), the optimal position (timing wise) may be achieved according to Table 1 below:

TABLE 1

| Number of pulses | |
|---|---|
| required | Refresh rate |
| 1 | T_{ON}*2/3 |
| 2 | T_{ON}*2/5 |
| 3 | T_{ON}*2/7 |
| 4 | T_{ON}*2/9 |
| 5 | T_{ON}*2/11 |
| 5 | T_{ON}*2/13 |
| 7 | T_{ON}*2/15 |
| 8 | T_{ON}*2/17 |

For example, in a case of a single refresh pulse, Table 1 indicates that the refresh rate is T_{ON}*⅔. As a result of this refresh rate (rate at which refresh pulses are generated), the signal pulse of opposite polarity will be exactly between the refresh pulse at T_{ON}*⅔ and the next potential refresh pulse at T_{ON}*4/3.

From Table 1, a general equation for the refresh rate versus number of pulses is given by the following equation:

$$Refresh\_rate ( Nr ) = {T}_{ON} * 2 / ( 1 + Nr * 2 ) , \qquad ( EQ . 1 )$$

with Nr being the number of refresh pulses.

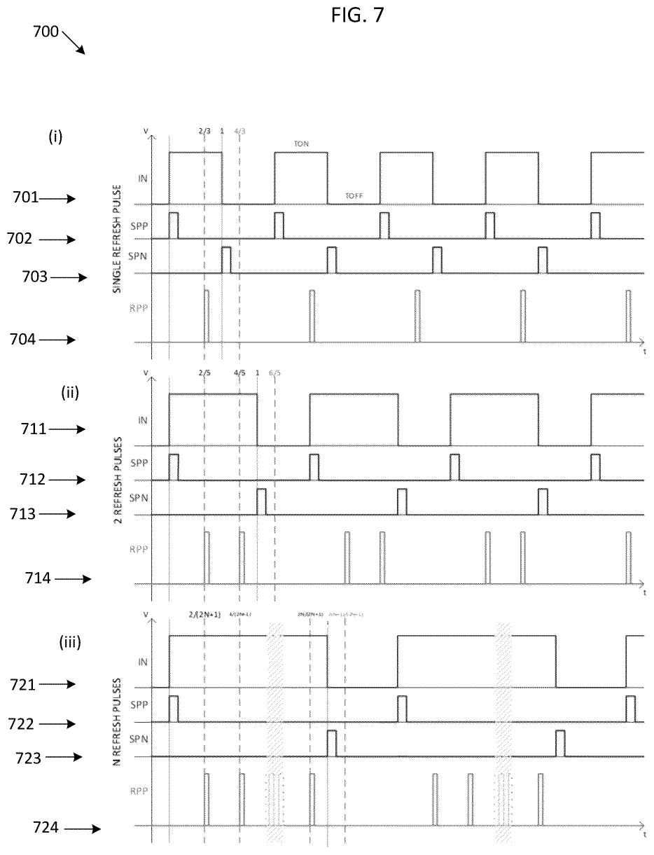

FIG. 7 is an example timing diagram 700 representing an equation of pulse positions verses number of refresh pulses (e.g., Equation 1) in accordance with the present disclosure. Timing diagram 700 shows the pulse positioning verses number of refresh pulses for three different pulse-number scenarios, i.e., Scenario (i) for one pulse, Scenario (ii) for two pulses, and Scenario (iii) for N pulses, in accordance with Table 1 and/or Equation 1.

Scenario (i) for one refresh pulse shows V_{IN} at 701 with an on time (T_{ON}) and an off time (T_{OFF}) defining a period (T) between successive pulses and a duty cycle. Corresponding positive signal pulses (SPP) and negative signal pulse (SPN) are shown at 702 and 703, respectively. Refresh power pulse (RPP), at 704, is shown starting at ⅔ T_{ON}, in accordance with Equation 1 and Table 1.

Scenario (ii) for two refresh pulses shows V_{IN} at 711 with an on time (T_{ON}) and an off time (T_{OFF}) defining a period (T) between successive pulses and a duty cycle. Corresponding positive signal pulses (SPP) and negative signal pulse (SPN) are shown at 712 and 713, respectively. Refresh power pulses (RPP), at 714, are shown starting at ⅖ T_{ON} and ⅘ T_{ON}, in accordance with Equation 1 and Table 1.

Scenario (iii) for N refresh pulses shows V_{IN} at 721 with an ON time (T_{ON}) and an OFF time (T_{OFF}) defining a period (T) between successive pulses and a duty cycle. Corresponding positive signal pulses (SPP) and negative signal pulse (SPN) are shown at 722 and 723, respectively. Refresh power pulses (RPP), at 724, are shown starting at 2/(2N+1) T_{ON}, 4/(2N+1) T_{ON}, and 2N/(2N+1) T_{ON}, in accordance with Equation 1.

For situations when T_{ON} is longer than a specified value, a simpler scheme (than the pulse positioning scheme using Table 1 and/or Equation 1, described above) with a defined refresh rate (T_{RMIN}) may be used. For example, in such situations, the refresh process can be started when on the rising edge of the Vin and the refresh pulses are produced at a rate determined by T_{RMIN}. A suitable scheme to avoid clashes is to have two different values of T_{RMIN}, i.e., T_{RMIN1} and T_{RMIN2}, which are only different by a few percent. When a clash is encountered, the system changes from T_{RMIN1} to T_{RMIN2}. In response to a subsequent clash, the system can move the refresh rate back to T_{RMIN1}. This scheme can minimize or facilitate minimization of the clashing for such low refresh rate scenarios.

In the schemes above, the focus has been on generating refresh pulses for the time when V_{IN} is high. There may also be a need for refresh pulses to maintain power when V_{IN} is low. Embodiments of the present disclosure can provide refresh pulses to maintain power when V_{IN} is low by duplicating (providing duplicates of) the circuits and schemes described above for V_{IN} high; these circuits are then fed by the inverse of V_{IN} and in this way refresh (reset) pulses are generated for the time when V_{IN} is low.

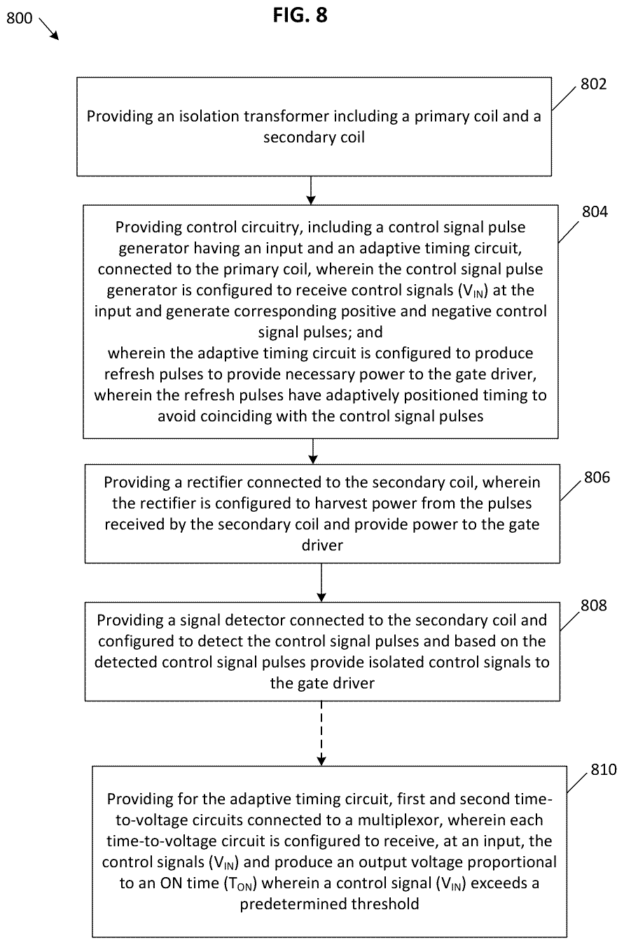

FIG. 8 is a diagram showing an example method 800 of fabricating a high-side driver providing adaptive power refresh pulse timing, in accordance with the present disclosure. Method 800 can include providing an isolation transformer including a primary coil and a secondary coil, as described at 802. Control circuitry, including a control signal pulse generator having an input and an adaptive timing circuit, can be provided which is connected to the primary coil, where the control signal pulse generator is configured to receive control signals (V_{IN}) at the input and generate corresponding positive and negative control signal pulses, where the adaptive timing circuit is configured to produce refresh pulses to provide necessary power to the gate driver, and where the refresh pulses have adaptively positioned timing to avoid coinciding with the control signal pulses, as described at 804.

A rectifier can be provided that is connected to the secondary coil, where the rectifier is configured to harvest power from the pulses received by the secondary coil and provide power to the gate driver, as described at 806. A signal detector can be provided that is connected to the secondary coil and configured to detect the control signal pulses and based on the detected control signal pulses provide isolated control signals to the gate driver, as described at 808. In some embodiments, method 800 can include providing for the adaptive timing circuit, first and second time-to-voltage circuits connected to a multiplexor, wherein each time-to-voltage circuit is configured to receive, at an input, the control signals (V_{IN}) and produce an output voltage proportional to an ON time (T_{ON}) wherein a control signal (V_{IN}) exceeds a predetermined threshold, as described at 810.

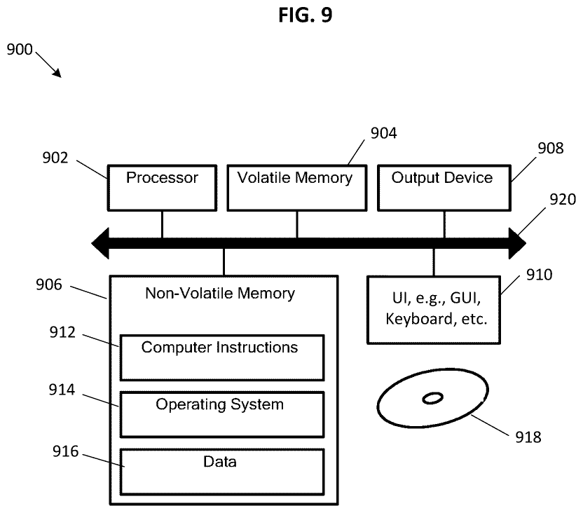

FIG. 9 shows an example computing system 900 in accordance with the present disclosure. System 900 (and/or similar or equivalent systems) can perform all or at least a portion of the processing, e.g., steps in the algorithms and methods as described herein. Such processing can include but is not limited to: controlling timing of refresh pulses delivered to high-side power transistors.

The computer system 900 can includes a processor 902, a volatile memory 904, a non-volatile memory 906 (e.g., hard disk), an output device 908 and a user input or interface (UI) 910, e.g., graphical user interface (GUI), a mouse, a keyboard, a display, and/or any common user interface, etc. The non-volatile memory (non-transitory storage medium) 906 stores computer instructions 912 (a.k.a., machine-readable instructions or computer-readable instructions) such as software (computer program product), an operating system 914 and data 916. In one example, the computer instructions 912 are executed by the processor 902 out of (from) volatile memory 904. In one embodiment, an article/apparatus 918 (e.g., a storage device or medium such as a hard disk, an optical disc, magnetic storage tape, optical storage tape, flash drive, etc.) includes or stores the non-transitory computer-readable instructions.

Processing may be implemented in hardware, software, or a combination of the two. Processing may be implemented in computer programs executed on programmable computers/machines that each includes a processor, a storage medium or other article of manufacture that is readable by the processor (including volatile and non-volatile memory and/or storage elements), and optionally at least one input device, and one or more output devices. Program code may be applied to data entered using an input device or input connection (e.g., port or bus) to perform processing and to generate output information.

The system 900 can perform processing, at least in part, via a computer program product, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer. Processing may also be implemented as a machine-readable storage medium, configured with a computer program, where upon execution, instructions in the computer program cause the computer to operate.

Processing may be performed by one or more programmable processors executing one or more computer programs to perform the functions of the system. All or part of the system may be implemented as special purpose logic circuitry, e.g., an FPGA (field programmable gate array) and/or an ASIC (application-specific integrated circuit).

Accordingly, embodiments and/or examples of the inventive subject matter can afford various benefits relative to prior art techniques. For example, embodiments and examples of the present disclosure can enable or facilitate improved power delivery for power (switching) transistors, particularly at low frequencies of operation.

Various embodiments of the concepts, systems, devices, structures, and techniques sought to be protected are described above with reference to the related drawings. Alternative embodiments can be devised without departing from the scope of the concepts, systems, devices, structures, and techniques described. For example, in some embodiments, primary and/or secondary transformer coils may have a whole number or a fractional number of turns (loops or structures configured around a related magnetic core), e.g., 1.5, 2.5, 1.75, 1.8, 2.25, 5, 6.5, 8.8, etc.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more” and “at least one” may indicate any integer number greater than or equal to one, i.e., one, two, three, four, etc.; those terms, however, may refer to fractional numbers/values where context admits, e.g., a number of loops in a transformer coil may be a plurality that includes a fractional value, e.g., 1.6, 2.75, 3.5, 4.25, etc. The term “plurality” may indicate any integer number greater than or equal to two, i.e., two, three, four, etc.; that term, however, may refer to fractional numbers/values greater than one, e.g., 1.2, 1.8, 2.66, etc., where context admits. The term “connection” can include an indirect connection and/or a direct connection.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (+) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and implemented in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. An adaptive power delivery circuit for an isolated gate driver, the gate driver comprising:
an isolation transformer including a primary coil and a secondary coil;
control circuitry, including a control signal pulse generator having an input and an adaptive timing circuit, connected to the primary coil,
wherein the control signal pulse generator is configured to receive control signals (V_{IN}) at the input and generate corresponding positive and negative control signal pulses; and
wherein the adaptive timing circuit is configured to produce refresh pulses to provide necessary power to the gate driver, wherein the refresh pulses have adaptively positioned timing to avoid coinciding with the control signal pulses; and
a rectifier connected to the secondary coil, wherein the rectifier is configured to harvest power from the pulses received by the secondary coil and provide power to the gate driver; and
a signal detector connected to the secondary coil and configured to detect the control signal pulses and based on the detected control signal pulses provide isolated control signals to the gate driver.

2. The circuit of claim 1, wherein the adaptive timing circuit includes first and second time-to-voltage circuits connected to a multiplexor, wherein each time-to-voltage circuit is configured to receive, at an input, the control signals (V_{IN}) and produce as an output signal an output voltage (V_{T}) proportional to an ON time (T_{ON}) wherein a control signal (V_{IN}) exceeds a predetermined threshold.

3. The circuit of claim 2, wherein each time-to-voltage circuit includes a switch configured between a current source and a capacitor (C₁), wherein the switch is configured to be activated by the control signals (V_{IN}).

4. The circuit of claim 2, wherein the multiplexor is configured to produce an output signal (V_{T}) that includes the output signal (V_{TON1}) from the first time-to-voltage circuit at a first time cycle (N) and the output signal (V_{TON2}) from the second time-to-voltage circuit at a subsequent time cycle (N+1).

5. The circuit of claim 3, wherein the multiplexor is configured to produce the output signal (V_{T}) as the output signal from the first time-to-voltage circuit alternating, on a cycle-by-cycle basis, with the output signal from the second time-to-voltage circuit.

6. The circuit of claim 2, wherein the adaptive timing circuit further comprises a voltage-controlled oscillator (VCO) circuit configured to receive the output signal (V_{T}) from the multiplexor and produce the refresh pulses with a desired time period between successive refresh pulses.

7. The circuit of claim 6, wherein the desired time period is a selected fraction of the time period corresponding to the multiplexor output signal (V_{T}) for a given time cycle.

8. The circuit of claim 6, wherein the VCO circuit comprises a switch configured between a current source and a charging capacitor (C₂), and wherein the VCO circuit includes a comparator configured to generate a refresh pulse when a voltage across the charging capacitor (C₂) exceeds a threshold voltage.

9. The circuit of claim 7, wherein the charging capacitor (C₂) is substantially equal to the capacitor (C₁) of the time-to-voltage circuits.

10. The circuit of claim 7, wherein the VCO circuit is configured to start an oscillator cycle at a rising edge of a control signal pulse.

11. The circuit of claim 8, wherein the current source of the VCO circuit includes a current mirror, and wherein the VCO circuit is configured to provide a current that is a desired scalar multiple (X) of the current source of the time-to-voltage circuits.

12. The circuit of claim 11, wherein the VCO circuit has an oscillator cycle period that is a corresponding reciprocal scaled version (1/X) of the cycle period of multiplexor output signal (V_{T}) for a given time cycle (N).

13. The circuit of claim 8, wherein threshold voltage is set to the multiplexor output signal (V_{T}).

14. The circuit of claim 13, wherein the adaptive timing circuit is configured to produce a plurality of refresh pulses for a given time cycle (N).

15. The circuit of claim 13, wherein a refresh rate (NR) of the plurality of refresh pulses is given by
$${N}_{R} = \frac{{T}_{ON} \times 2}{( 1 + 2 \times {N}_{R} )} ,$$
wherein T_{ON} is the ON time corresponding to the multiplexor output signal (V_{T}) for a current time cycle.

16. The circuit of claim 8, wherein for T_{ON} exceeding a predetermined threshold time, the adaptive timing circuit is configured to set the oscillator threshold voltage to a first desired voltage (V_{TRMIN1}) corresponding to a first desired refresh pulse rate (T_{RMIN1}).

17. The circuit of claim 16, wherein, in response to a pulse clash, the adaptive timing circuit is configured to switch the oscillator threshold voltage from the first desired voltage (V_{TRMIN1}) corresponding to the first desired refresh pulse rate (T_{RMIN1}) to a second desired voltage (V_{TRMIN2}) corresponding to a second desired refresh pulse rate (T_{RMIN2}).

18. The circuit of claim 17, wherein the second desired pulse rate (T_{RMIN2}) is withing a range of about ±5% of the first desired pulse rate (T_{RMIN1}).

19. The circuit of claim 8, wherein threshold is set to the multiplexor output signal (V_{T}).

20. The circuit of claim 2, wherein the capacitor is configured in parallel with a reset switch configured to receive the refresh pulse from the oscillator as a reset pulse.

21. The circuit of claim 1, wherein the signal detector includes a latch, wherein positive and negative pulses received from the secondary coil operate to set and reset the latch to form the control signal pulses.

22. The circuit of claim 1, further comprising an inverter provided at the input to the control signal pulse generator.

23. The circuit of claim 1, further comprising a gate driver connected to the secondary coil, wherein the gate driver is configured to control operation of a semiconductor power switch.

24. A method of making an adaptive power delivery circuit for providing power to a gate driver, the method comprising:
providing an isolation transformer including a primary coil and a secondary coil;
providing control circuitry, including a control signal pulse generator having an input and an adaptive timing circuit, connected to the primary coil,
wherein the control signal pulse generator is configured to receive control signals (V_{IN}) at the input and generate corresponding positive and negative control signal pulses; and
wherein the adaptive timing circuit is configured to produce refresh pulses to provide necessary power to the gate driver, wherein the refresh pulses have adaptively positioned timing to avoid coinciding with the control signal pulses; and
providing a rectifier connected to the secondary coil, wherein the rectifier is configured to harvest power from the pulses received by the secondary coil and provide power to the gate driver; and
providing a signal detector connected to the secondary coil and configured to detect the control signal pulses and based on the detected control signal pulses provide isolated control signals to the gate driver.

25. The method of claim 24, wherein the adaptive timing circuit includes first and second time-to-voltage circuits connected to a multiplexor, wherein each time-to-voltage circuit is configured to receive, at an input, the control signals (V_{IN}) and produce an output voltage proportional to an ON time (T_{ON}) wherein a control signal (V_{IN}) exceeds a predetermined threshold.

26. The method of claim 25, wherein each time-to-voltage circuit includes a switch configured between a current source and a capacitor (C₁), wherein the switch is configured to be activated by the control signals (V_{IN}).

27. The method of claim 25, wherein the multiplexor is configured to produce an output signal (V_{T}) that includes the output signal (V_{TON1}) from the first time-to-voltage circuit at a first time cycle (N) and the output signal (V_{TON2}) from the second time-to-voltage circuit at a subsequent time cycle (N+1).

28. The method of claim 26, wherein the multiplexor is configured to produce the output signal (V_{T}) as the output signal from the first time-to-voltage circuit alternating, on a cycle-by-cycle basis, with the output signal from the second time-to-voltage circuit.

29. The method of claim 27, wherein the adaptive timing circuit further comprises a voltage-controlled oscillator (VCO) circuit configured to receive the output signal (V_{T}) from the multiplexor and produce the refresh pulses with a desired time period between successive refresh pulses.

30. The method of claim 29, wherein the desired time period is a selected fraction of the time period corresponding to the multiplexor output signal (V_{T}) for a given time cycle.

31. The method of claim 29, wherein the VCO circuit comprises a switch configured between a current source and a charging capacitor (C₂), and wherein the VCO circuit includes a comparator configured to generate the oscillator output pulse when a voltage across the charging capacitor exceeds a threshold voltage.

32. The method of claim 30, wherein the charging capacitor (C₂) is substantially equal to the capacitor (C₁) of the time-to-voltage circuits.

33. The method of claim 30, wherein the VCO circuit is configured to start an oscillator cycle at a rising edge of a control signal pulse.

34. The method of claim 31, wherein the current source of the VCO circuit includes a current mirror, and wherein the VCO circuit is configured to provide a current that is a desired scalar multiple (X) of the current source of the time-to-voltage circuits.

35. The method of claim 34, wherein the VCO circuit has an oscillator cycle period that is a corresponding reciprocal scaled version (1/X) of the cycle period of multiplexor output signal (V_{T}) for a given time cycle (N).

36. The method of claim 31, wherein threshold voltage is set to the multiplexor output signal (V_{T}).

37. The method of claim 36, wherein the adaptive timing circuit is configured to produce a plurality of refresh pulses for a given time cycle (N).

38. The method of claim 26, wherein a refresh rate (NR) of the plurality of refresh pulses is given by
$${N}_{R} = \frac{{T}_{ON} \times 2}{( 1 + 2 \times {N}_{R} )} ,$$
wherein T_{ON} is the ON time corresponding to the multiplexor output signal (V_{T}) for a current time cycle.

39. The method of claim 31, wherein for T_{ON} exceeding a predetermined threshold time, the adaptive timing circuit is configured to set the oscillator threshold voltage to a first desired voltage (V_{TRMIN1}) corresponding to a first desired refresh pulse rate (T_{RMIN1}).

40. The method of claim 39, wherein, in response to a pulse clash, the adaptive timing circuit is configured to switch the oscillator threshold voltage from the first desired voltage (V_{TRMIN1}) corresponding to the first desired refresh pulse rate (T_{RMIN1}) to a second desired voltage (V_{TRMIN2}) corresponding to a second desired refresh pulse rate (T_{RMIN2}).

41. The method of claim 40, wherein the second desired pulse rate (T_{RMIN2}) is withing a range of about ±5% of the first desired pulse rate (T_{RMIN1}).

42. The method of claim 31, wherein threshold is set to the multiplexor output signal (V_{T}).

43. The method of claim 25, wherein the capacitor is configured in parallel with a reset switch configured to receive the refresh pulse from the oscillator as a reset pulse.

44. The method of claim 24, wherein the signal detector includes a latch, wherein positive and negative pulses received from the secondary coil operate to set and reset the latch to form the control signal pulses.

45. The method of claim 24, further comprising providing an inverter provided at the input to the control signal pulse generator.

46. The method of claim 24, further comprising providing a gate driver connected to the secondary coil, wherein the gate driver is configured to control operation of a semiconductor power switch.
